(19) United States
(12) Patent Application Publication
(10) Pub. No.: US 2018/0226391 A1
(43) Pub. Date: Aug. 9, 2018

(54) THIN FILM LC COMPONENT AND MOUNTING STRUCTURE OF SAME

(71) Applicant: Murata Manufacturing Co., Ltd., Nagaokakyo-shi (JP)

(72) Inventor: NORIYUKI UEKI, Nagaokakyo-shi (JP)

(21) Appl. No.: 15/928,217

(22) Filed: Mar. 22, 2018

Related U.S. Application Data
(63) Continuation of application No. PCT/JP2016/078552, filed on Sep. 28, 2016.

(30) Foreign Application Priority Data
Oct. 2, 2015 (JP) 2015-196392

(51) Int. Cl. H01L 27/01; H01L 49/02; H01L 23/498; H01L 23/00; H01G 4/33; H01G 4/40; H01F 27/28; H01F 27/40

(52) U.S. Cl. CPC H01L 27/016; H03H 1/00; H01L 28/55; H01L 28/60; H01L 23/49827; H01L 23/49816; H01L 24/16; H01G 4/33; H01G 4/40; H01F 27/2804; H01F 27/40; H01L 2924/19011; H01L 2924/19015; H01L 2924/19042; H01L 2924/19041; H01L 2924/19103; H01L 2924/30107; H01L 2224/16225; H01L 28/10

(57) ABSTRACT

A thin film LC component includes a substrate that has a first surface and a second surface opposing to each other, a thin film capacitor that is formed on the first surface by a thin film process, a thin film inductor that is formed in a region of the second surface by a thin film process, the region at least partially overlapping the thin film capacitor when viewed in plan, interlayer connection conductors that are formed in the substrate and connect the thin film capacitor and the thin film inductor to each other, an insulating layer that is formed over the first surface and covers the thin film capacitor, and a plurality of terminal electrodes that are formed on a surface of the insulating layer and are connected to the thin film capacitor and the thin film inductor.

### CROSS REFERENCE TO RELATED APPLICATIONS

The present application is a continuation of International application No. PCT/JP2016/078552, filed Sep. 28, 2016, which claims priority to Japanese Patent Application No. 2015-196392, filed Oct. 2, 2015, the entire contents of each of which are incorporated herein by reference.

### TECHNICAL FIELD

The present invention relates to an LC component, and more particularly to a thin film LC component suitable for reduction of thickness and to a mounting structure of the thin film LC component.

### BACKGROUND ART

There is known a thin film IDP (Integrated Passive Device) in which an inductor and a capacitor are integrally formed on a silicon substrate or an alumina substrate by a thin film process (see, e.g., Japanese Unexamined Patent Application Publication No. 6-53406 and Japanese Unexamined Patent Application Publication No. 2001-44778). Japanese Unexamined Patent Application Publication No. 6-53406 discloses a technique of, in a step of fabricating a thin film circuit, forming a dielectric film for a thin film LC capacitor and an interlayer insulating film for a thin film inductor at the same time.

Japanese Unexamined Patent Application Publication No. 2001-44778 discloses a technique of constituting a capacitor by successively forming a first electrode layer, a dielectric layer, and a second electrode layer on a substrate, and forming, on the capacitor, a planar inductor that is made up of magnetic films and a coil, thereby ensuring isolation between the capacitor and the inductor.

Because the IPD is a passive component formed by the thin film process, its thickness can be considerably reduced in comparison with thicknesses of passive components that are formed by a thick film process and a sheet multilayer process. However, when the inductor and the capacitor are flush with each other as in Japanese Unexamined Patent Application Publication No. 6-53406, a necessary substrate area is increased, and an increase in size of the thin film IPD is unavoidable. On the other hand, when the capacitor is formed on the substrate and the inductor is formed on the capacitor as in Japanese Unexamined Patent Application Publication No. 2001-44778, the necessary substrate area is reduced. However, when such an LC passive component is mounted to a printed wiring board or the like, a distance between a circuit on the printed wiring board and the capacitor is increased relatively, thus causing a parasitic inductance therebetween. Accordingly, electrical characteristics of the LC passive component change depending on a state of mounting to the printed wiring board or the like.

An object of the present invention is to provide a thin film LC component being thin and having a small area, in which a parasitic inductance of a thin film capacitor is suppressed, and to provide a mounting structure of the thin film LC component.

### BRIEF SUMMARY OF THE INVENTION

A thin film LC component, comprising:

a substrate that has first and second opposing surfaces;

a thin film capacitor located on the first surface;

a thin film inductor located on a region of the second surface, the region at least partially overlapping the thin film capacitor when viewed in plan;

interlayer connection conductors located in the substrate and connecting the thin film capacitor to the thin film inductor;

an insulating layer located over the first surface and covering the thin film capacitor; and

a plurality of terminal electrodes located on a surface of the insulating layer and being connected to both the thin film capacitor and the thin film inductor, the terminal electrodes being connected to a circuit on a mounting substrate.

With the features described above, an area of a region where the thin film capacitor and the thin film inductor are formed is reduced when viewed in plan. Furthermore, since the terminal electrodes are formed on the substrate not at the side where the thin film inductor is formed, but at the side where the thin film capacitor is formed, the thin film capacitor can be arranged at a shortest distance relative to a circuit formed on a printed wiring board (mounting substrate), and a parasitic inductance is reduced. Moreover, since the substrate is interposed between the thin film inductor and the thin film capacitor, namely since the thin film inductor is positioned away from the thin film capacitor, an eddy current is less apt to flow in electrode films of the thin film capacitor. Hence the thin film inductor having a higher Q-value is constituted.

Preferably, each of the thin film inductor and the thin film capacitor has a first end and a second end, the first end of the thin film capacitor and the second end of the thin film inductor are connected to each other, and the plurality of terminal electrodes are constituted by at least three terminal electrodes that are connected respectively to the first end of the thin film capacitor, a second end of the thin film capacitor, and a first end of the thin film inductor. With the features described above, it is just needed from an electrical point of view that the three terminal electrodes are disposed in a state exposed to the outside. Thus, an LC low pass filter or a smoothing circuit, for example, can be constituted just by connecting those terminal electrodes to the circuit on the substrate.

In an embodiment, the thin film inductor is constituted by a plurality of thin film inductors each having a first end and a second end, and the plurality of terminal electrodes include a terminal electrode that is connected to the first ends of the plurality of thin film inductors. With the features described above, low pass filters or smoothing circuits having different time constants can be selectively used in combination of plural inductors and a common capacity.

In an embodiment, the thin film capacitor includes a first electrode film parallel to the first surface, a second electrode film opposing to the first electrode film, and a dielectric thin film interposed between the first electrode film and the second electrode film, the dielectric thin film being a barium strontium titanate thin film. With the features described above, the thin film capacitor with a high capacitance in spite of having a small area can be constituted, and hence the thin film LC component having a small size can be constituted.

In an embodiment, a total thickness of the substrate, the thin film capacitor, the thin film inductor, and the insulating layer is not more than 100 When the total thickness has such a size, the thin film LC component can be disposed in a gap between a face plane of a semiconductor chip and a mounting substrate, the semiconductor chip being face-down mounted to the mounting substrate with bumps interposed therebetween.

In another embodiment a mounting structure is provided for a thin film LC component, the mounting structure being adapted to mount a semiconductor chip, a capacitor, and an inductor to a mounting substrate. The semiconductor chip is face-down mounted to the mounting substrate with bumps interposed therebetween. The capacitor and the inductor are constituted as a thin film LC component comprising a substrate that has a first surface and a second surface opposing to each other, a thin film capacitor that is formed on the first surface by a thin film process, a thin film inductor that is formed in a region of the second surface by a thin film process, the region at least partially overlapping the thin film capacitor when viewed in plan, interlayer connection conductors that are formed in the substrate and connect the thin film capacitor and the thin film inductor to each other, an insulating layer that is formed over the first surface and covers the thin film capacitor, and terminal electrodes that are formed on a surface of the insulating layer and are connected to the thin film capacitor and the thin film inductor. The thin film LC component is disposed in a gap between the mounting substrate and the semiconductor chip.

With the features described above, the thin film LC component being thin and having a small area, or the thin film LC component in which a parasitic inductance of the thin film capacitor is suppressed can be mounted to the mounting substrate together with the semiconductor chip at a high density.

The present invention makes it possible to provide a thin film LC component which is thin and which has a small area and the parasitic inductance is suppressed. The present invention further provides a small-sized electronic device including the thin film LC component.

### BRIEF DESCRIPTION OF DRAWINGS

FIG. 1(A) is a plan view of a thin film LC component 101 according to a first embodiment, FIG. 1(C) is a bottom view of the thin film LC component 101, and FIG. 1(B) is a vertical sectional view of the thin film LC component 101 taken along a line X-X in FIGS. 1(A) and 1(C).

FIG. 2 is a circuit diagram of the thin film LC component 101.

FIG. 3(A) is a plan view illustrating a state where a plurality of thin films used to form a thin film capacitor are formed on a substrate 10, and FIG. 3(B) is a sectional view taken along a line X-X in FIG. 3(A).

FIG. 4(A) is a plan view illustrating a state after patterning the thin films in a thin film capacitor forming region, and FIG. 4(B) is a sectional view taken along a line X-X in FIG. 4(A).

FIG. 5(A) is a plan view illustrating a state after forming a solder resist film 31 in the thin film capacitor forming region, and FIG. 5(B) is a sectional view taken along a line X-X in FIG. 5(A).

FIG. 6(A) is a plan view illustrating a state after forming holes H1, H2 and H3 in the solder resist film 31, and FIG. 6(B) is a sectional view taken along a line X-X in FIG. 6(A).

FIG. 7(A) is a plan view illustrating a state after forming via electrodes 41, 42 and 43 and terminal electrodes 51, 52 and 53, and FIG. 7(B) is a sectional view taken along a line X-X in FIG. 7(A).

FIG. 8(A) is a plan view illustrating a state after forming a solder resist film 31 that partially covers the terminal electrodes 51, 52 and 53, and FIG. 8(B) is a sectional view taken along a line X-X in FIG. 8(A).

FIG. 9(A) is a plan view illustrating a state after forming holes H61 and H62 in the substrate 10, etc., and FIG. 9(B) is a sectional view taken along a line X-X in FIG. 9(A).

FIG. 10(A) is a plan view illustrating a state after forming through-silicon vias 61 and 62 in the substrate 10, and FIG. 10(B) is a sectional view taken along a line X-X in FIG. 10(A).

FIG. 11(C) is a bottom view illustrating a state after forming a conductor pattern 70 for a thin film inductor on a second surface S2 of the substrate 10, FIG. 11(A) is a plan view illustrating that state, and FIG. 11(B) is a sectional view taken along a line X-X in FIGS. 11(A) and 11(C).

FIG. 12 is an exploded perspective view of a thin film LC component 102 according to a second embodiment.

FIG. 13 is a perspective view of the thin film LC component 102.

FIG. 14(A) is a plan view illustrating a state after forming a thin film inductor TFL on a substrate 10L, and FIG. 14(B) is a sectional view taken along a line X-X in FIG. 14(A).

FIG. 15(A) is a plan view illustrating a state where the substrate 10L including the thin film inductor TFL formed thereon and a substrate 10C including a thin film capacitor TFC formed thereon are joined to each other at their back surfaces, and FIG. 15(B) is a sectional view taken along a line X-X in FIG. 15(A).

FIG. 16(A) is a plan view illustrating a state after forming electrode terminals 51, 52 and 53, and FIG. 16(B) is a sectional view taken along a line X-X in FIG. 16(A).

FIG. 17 is a sectional view of an electronic component of a SiP (system in a package) structure according to a third embodiment.

FIG. 18 is a conceptual view illustrating connection structures of smoothing circuits, which are connected to a microprocessor, according to a fourth embodiment.

FIGS. 19(A) and 19(B) are each a circuit diagram of a thin film LC component according to a fifth embodiment.

### DESCRIPTION OF THE PREFERRED EMBODIMENTS

Embodiments for carrying out the present invention will be described below in connection with several practical examples by referring to the drawings. In the drawings, the same members are denoted by the same reference signs. Although the embodiments are described in separated forms in consideration of easiness in explanation of principal matters and understanding, individual features of the different embodiments can be partially replaced or combined with each other. In the second and subsequent embodiments, description of common matters to those in the first embodiment is omitted, and only different points are described. In particular, similar advantageous effects obtained with similar features are not specifically described in each of the embodiments.

### First Embodiment

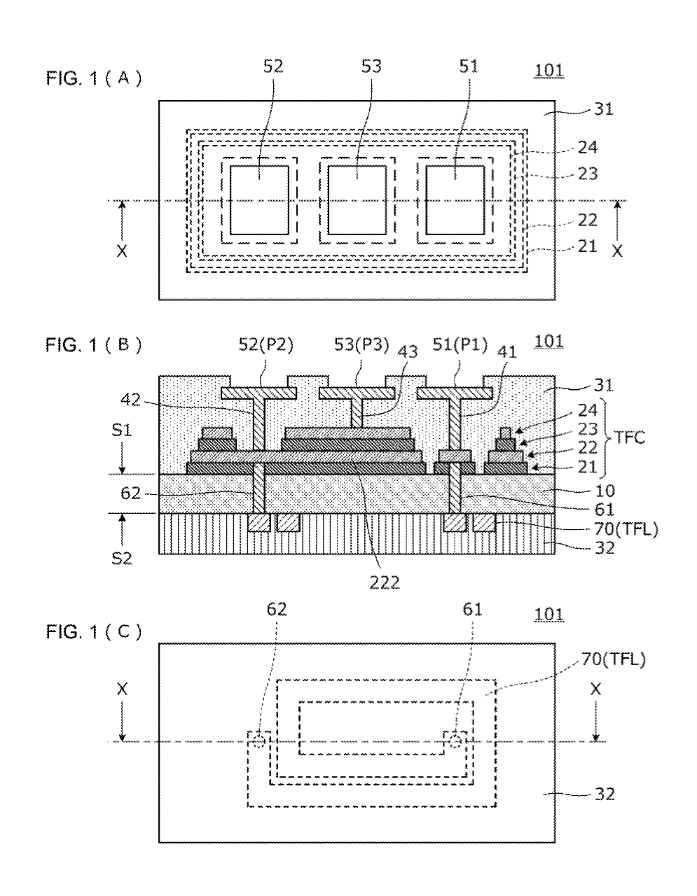

FIG. 1(A) is a plan view of a thin film LC component 101 according to a first embodiment, FIG. 1(C) is a bottom view of the thin film LC component 101, and FIG. 1(B) is a vertical sectional view of the thin film LC component 101 taken along a line X-X in FIGS. 1(A) and 1(C).

As best shown in FIG. 1(B), the thin film LC component 101 includes a substrate 10 having opposed first and second surfaces S1 and S2. A thin film capacitor TFC is formed on the first surface S1 and a thin film inductor TFL is formed on the second surface S2. The thin film inductor TFL is formed in a region of the substrate 10 which overlaps the thin film capacitor TFC when viewed in plan.

Through-silicon vias 61 and 62 connecting the thin film capacitor TFC and the thin film inductor TFL are formed in the substrate 10. A solder resist film (insulating layer) 31 covering the thin film capacitor TFC is formed on the first surface S1 of the substrate 10. Terminal electrodes 51, 52 and 53 connected to the thin film capacitor TFC and the thin film inductor TFL are formed on a surface of the solder resist film 31.

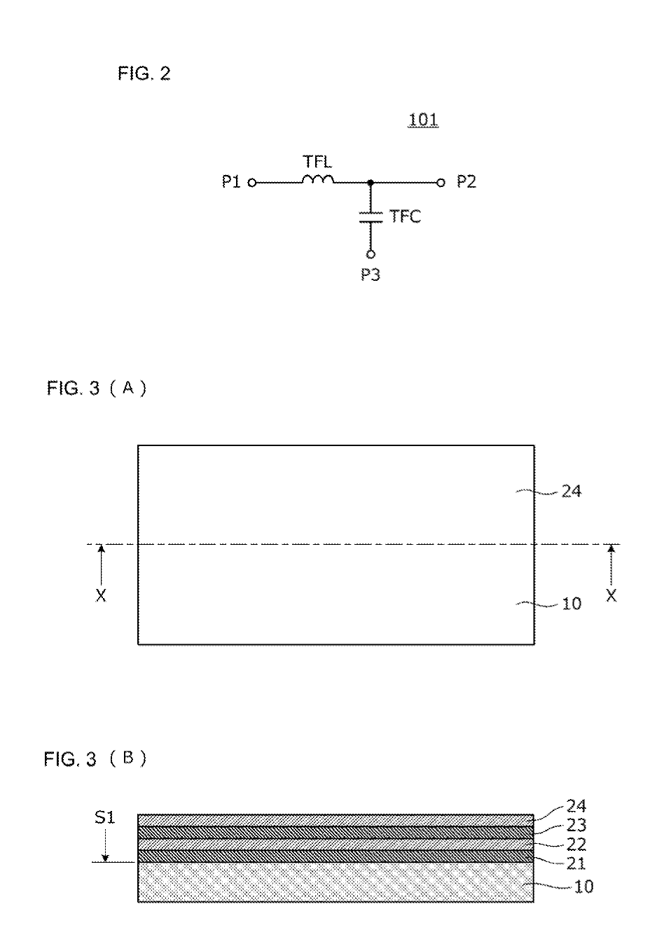

FIG. 2 is a circuit diagram of the thin film LC component 101. In FIG. 2, ports P1, P2 and P3 correspond respectively to the terminal electrodes 51, 52 and 53. In this embodiment the thin film LC component 101 is constituted by the thin film capacitor TFC connected between the ports P1 and P2, and the thin film inductor TFL connected between the ports P2 and P3.

The thin film LC component 101 according to this embodiment acts as a low pass filter or a smoothing circuit with the port P3 held at a ground potential, the port P1 being an input port, and the port P2 being an output port.

This embodiment has the following advantageous effects.

An area of a region where the thin film capacitor TFC and the thin film inductor TFL are formed is reduced when viewed in plan. Furthermore, since the terminal electrodes 51, 52 and 53 are formed on the substrate 10 not at the side where the thin film inductor TFL is formed, but at the side where the thin film capacitor TFC is formed, the thin film capacitor TFC can be arranged at a shortest distance relative to a circuit formed on a printed wiring board (mounting substrate), and a parasitic inductance is reduced. Therefore, a resonant frequency of LC serial resonance generated by the parasitic inductance and the thin film capacitor TFC can be made higher than a frequency band to be used, and low pass filter characteristics or smoothing characteristics can be obtained over a wide range.

Moreover, since the substrate 10 is interposed between the thin film inductor TFL and the thin film capacitor TFC, namely since the thin film inductor TFL is positioned away from the thin film capacitor TFC, an eddy current is less apt to flow in electrodes of the thin film capacitor TFC. Hence the thin film inductor TFL having a higher Q-value is constituted.

A detailed structure of the thin film LC component 101 illustrated in FIGS. 1(A), 1(B) and 1(C), and a manufacturing method for the thin film LC component 101 will be described below with reference to FIGS. 3 to 11, etc.

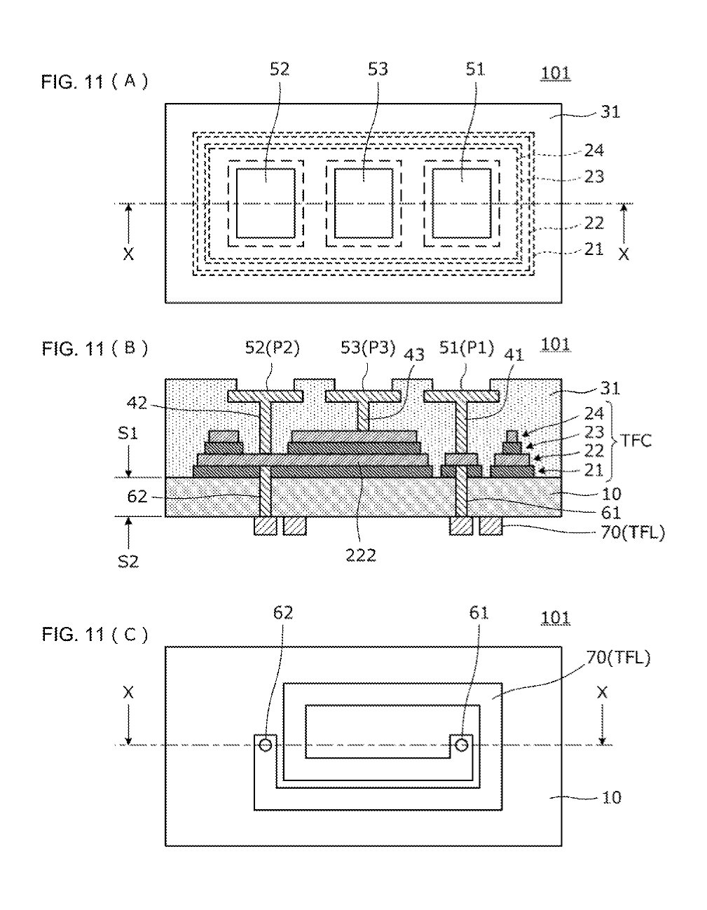

FIGS. 3(A), 4(A), 5(A), 6(A), 7(A), 8(A), 9(A), 10(A) and 11(A) are plan views illustrating individual steps, and FIGS. 3(B), 4(B), 5(B), 6(B), 7(B), 8(B), 9(B), 10(B) and 11(B) are sectional views, taken along lines X-X, illustrating the individual steps. FIG. 11(C) is a bottom view.

Step (1) In FIGS. 3(A) and 3(B), the substrate 10 is, for example, a high-resistance Si substrate. A BST film (barium strontium titanate film, (Ba,Sr)TiO3 film) 21, a Pt electrode film 22, a BST film 23, and a Pt electrode film 24 are successively formed on the first surface S1 of the substrate 10. The BST films are preferably each formed through a spin coating step and a firing step, and the Pt electrode films are each preferably formed by sputtering. The BST film 21 is utilized as an adhesion layer with respect to the Si substrate 10. Because the BST film 21 is unrelated to capacitance, a film other than the BST film may also be used insofar as the film act as an adhesion layer with respect to the Si substrate 10. The Pt electrode film may be formed as a film using another noble metal material, such as Au, having good electrical conductivity, high oxidation resistance, and a high melting point.

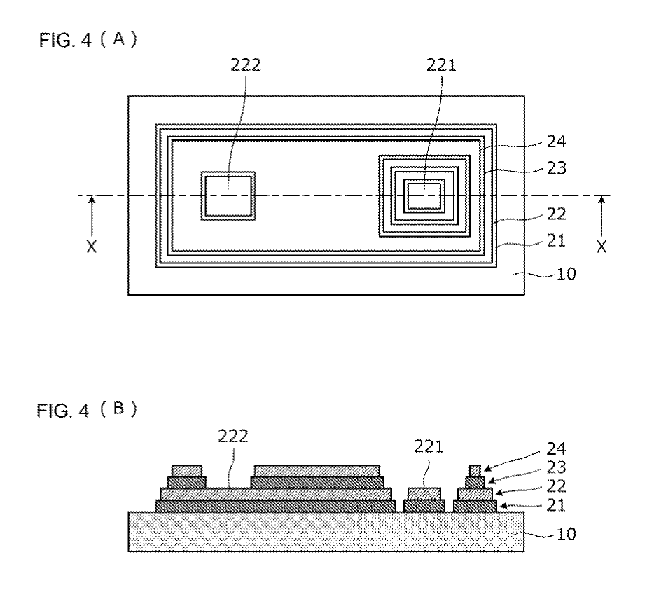

Step (2) As illustrated in FIGS. 4(A) and 4(B), patterning is performed on the BST films 21 and 23 and the Pt electrode films 22 and 24 by repeating photolithography a predetermined number of times. More specifically, a Pt electrode film 221 to be electrically conducted to the port P1 later is isolated and exposed, while a Pt electrode film 222 to be electrically conducted to the port P2 later is exposed.

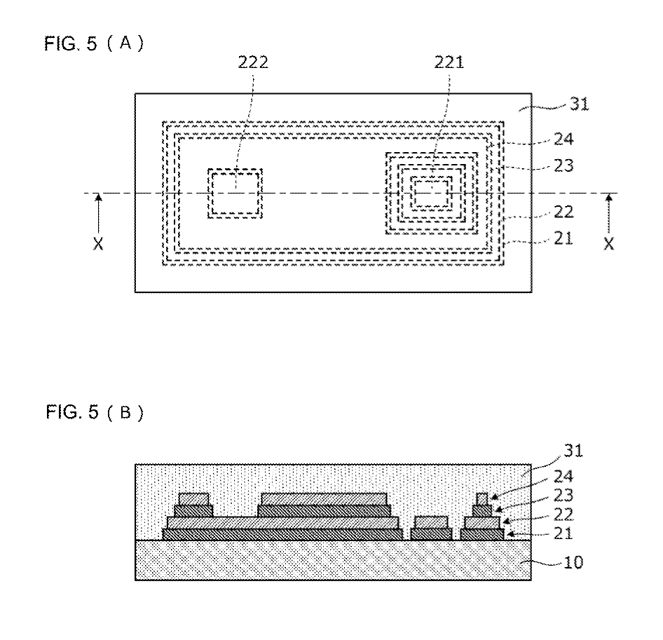

Step (3) As illustrated in FIGS. 5(A) and 5(B), the solder resist film 31 made of epoxy or polyimide, for example, is spin-coated.

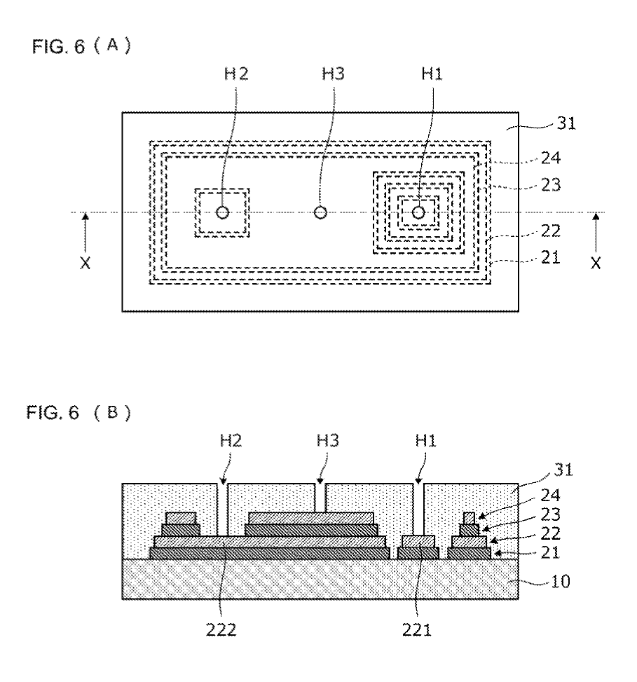

Step (4) As illustrated in FIGS. 6(A) and 6(B), holes H1, H2 and H3 are formed in the solder resist film 31.

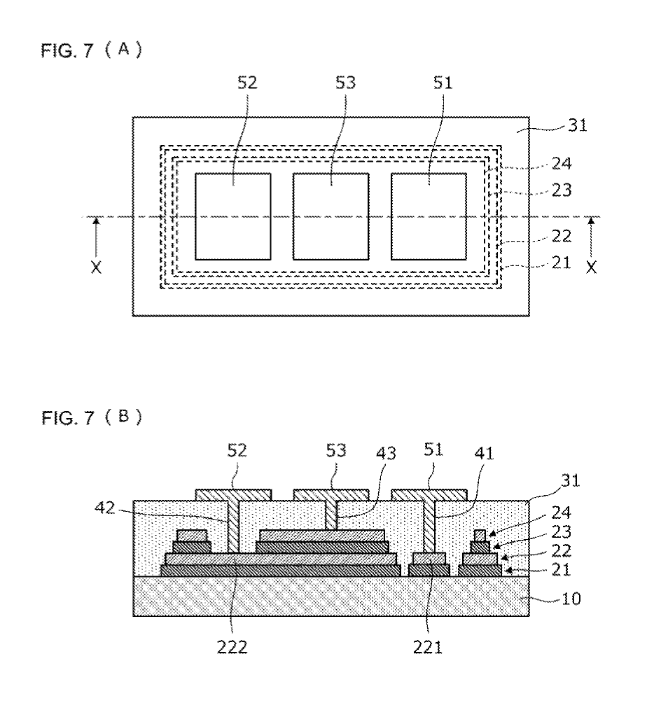

Step (5) As illustrated in FIGS. 7(A) and 7(B), a conductor film of, for example, Ti/Cu/Ti having thicknesses of 0.1 μm/1.0 is formed inside the holes H1, H2 and H3 and on a surface of the solder resist film 31 by sputtering. As a result, via electrodes 41, 42 and 43 are formed in the holes H1, H2 and H3, respectively. Thereafter, the terminal electrodes 51, 52 and 53 are formed by patterning the Ti/Cu/Ti film on the surface of the solder resist film 31.

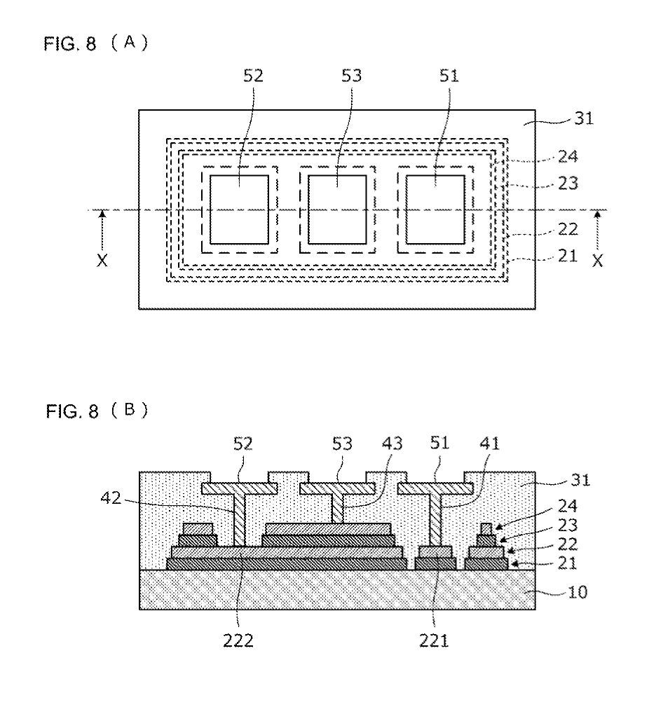

Step (6) As illustrated in FIGS. 8(A) and 8(B), an additional solder resist film 31 is formed, and the terminal electrodes 51, 52 and 53 are exposed.

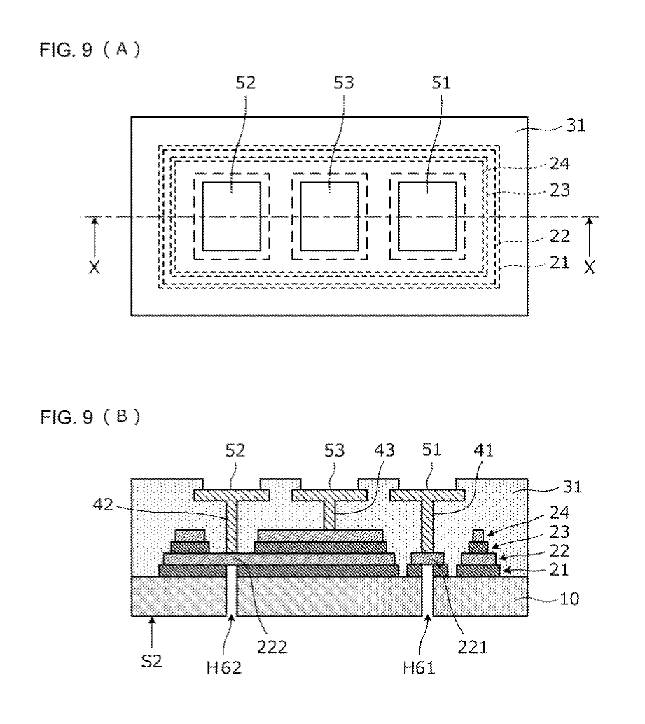

Step (7) As illustrated in FIGS. 9(A) and 9(B), holes H61 and H62 are bored in the substrate 10 by etching or drilling, for example.

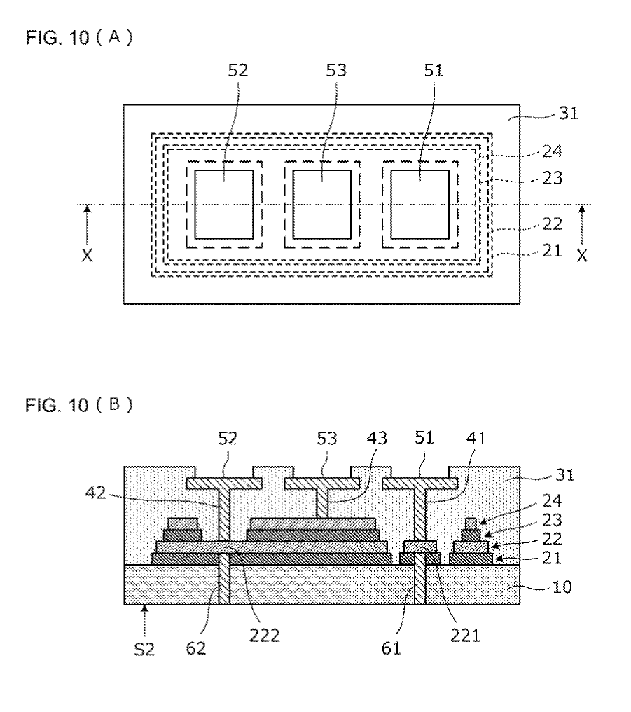

Step (8) As illustrated in FIGS. 10(A) and 10(B), a conductor film of Ti/Cu/Ti, for example, is formed inside the holes H61 and H62 and on the second surface S2 of the substrate 10. As a result, the through-silicon vias (TSV's) 61 and 62 are formed in the holes H61 and H62, respectively. Thereafter, the above-mentioned conductor film on the second surface S2 of the substrate 10 is removed by a CMP process, for example.

Step (9) As illustrated in FIGS. 11(A), 11(B) and 11(C), a conductor pattern 70 serving as the thin film inductor TFL is formed on the second surface S2 of the substrate 10 by forming a Cu plating film on the second surface S2 of the substrate 10, and then patterning the Cu plating film.

Step (10) Then, the thin film LC component 101 illustrated in FIGS. 1(A), 1(B) and 1(C) is obtained by spin-coating a solder resist film 32 made of epoxy or polyimide, for example, on the second surface S2 of the substrate 10.

Although FIGS. 3 to 11 illustrate a case where the thin film LC component 101 is in the form of a single component for convenience of explanation, the above-described processing is performed in units of a wafer and the wafer is finally divided into individual components (pieces) in practice.

### Second Embodiment

A second embodiment represents a thin film LC component 102 that is formed by integrating a thin film capacitor TFC and a thin film inductor TFL with each other, which are fabricated separately.

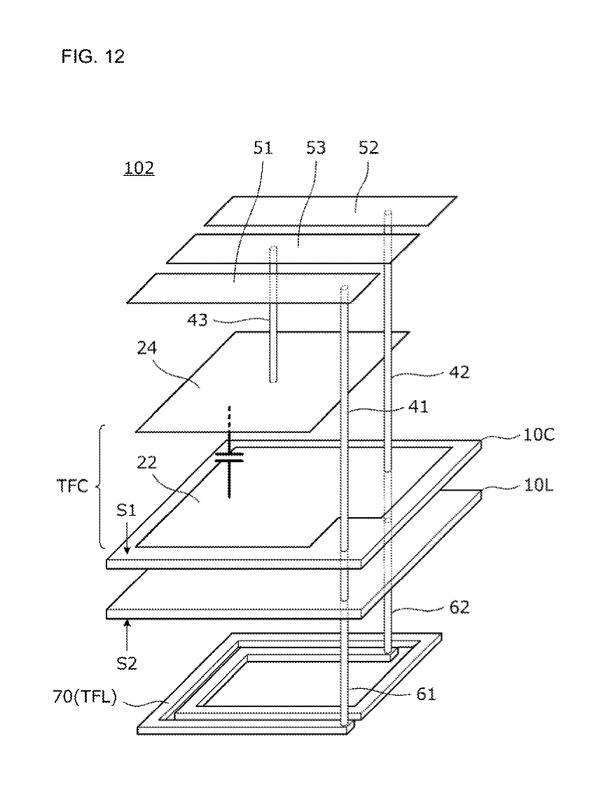

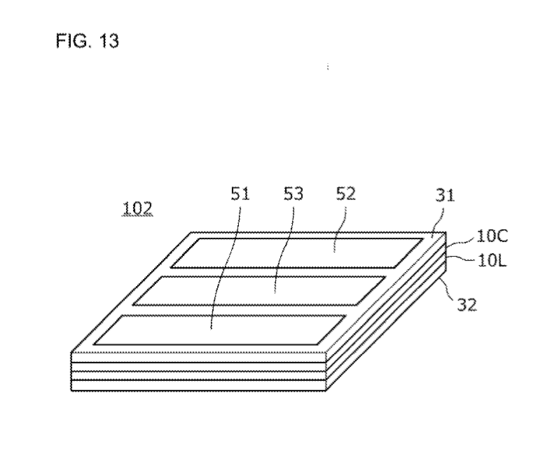

FIG. 12 is an exploded perspective view of the thin film LC component 102, and FIG. 13 is a perspective view of the thin film LC component 102. In FIG. 12, a dielectric film and an insulating film are omitted.

In the thin film LC component 102 according to this embodiment, the thin film capacitor TFC is located on a first surface S1 of a substrate 10C, and the thin film inductor TFL is located on a second surface S2 of a substrate 10L.

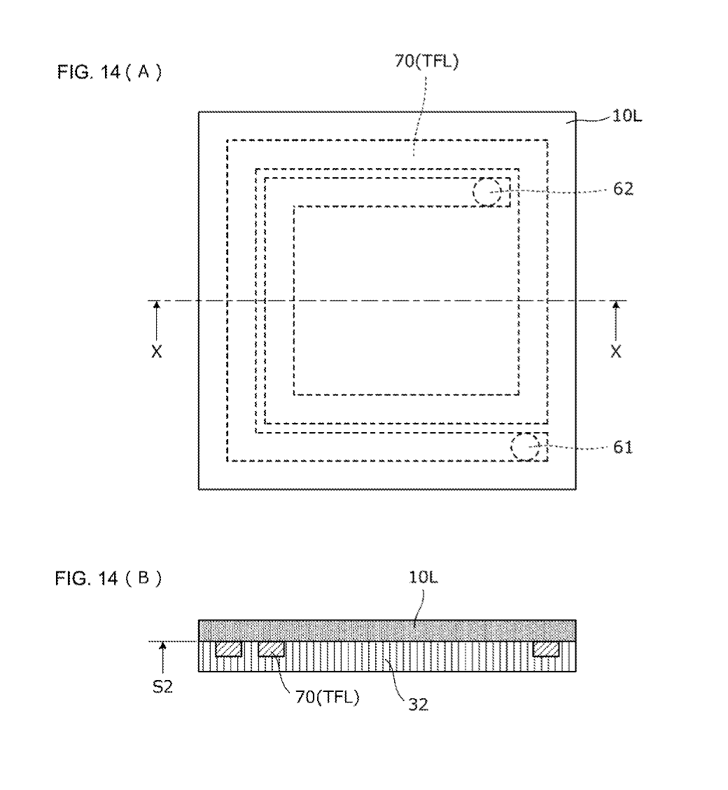

A detailed structure of the thin film LC component 102 according to this embodiment, and a manufacturing method for the thin film LC component 102 will be described below with reference to FIGS. 14 to 16, etc.

FIGS. 14(A), 15(A) and 16(A) are plan views illustrating individual steps, and FIGS. 14(B), 15(B) and 16(B) are sectional views, taken along lines X-X, illustrating the individual steps.

Step (1) In FIGS. 14(A) and 14(B), the substrate 10L is, for example, a high-resistance Si substrate. A conductor pattern 70 serving as the thin film inductor TFL is formed on the second surface S2 of the substrate 10L by forming a Cu plating film on the second surface S2 of the substrate 10L, and then patterning the Cu plating film.

Step (2) A solder resist film 32 covering the conductor pattern 70 is coated to be formed thereon. Thereafter, through-silicon vias (TSV's) 61 and 62 are formed in the substrate 10L. As a result, the thin film inductor TFL including the through-silicon vias 61 and 62 are constituted.

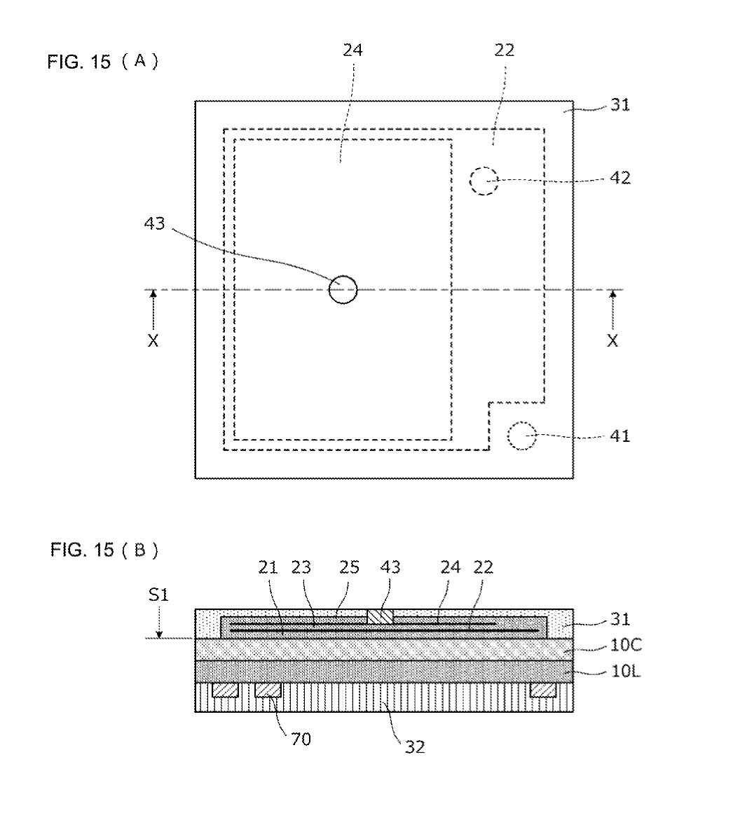

Step (3) As illustrated in FIGS. 15(A) and 15(B), a BST film 21, a Pt electrode film 22, a BST film 23, a Pt electrode film 24, and a BST film 25 are successively formed on the first surface S1, and a solder resist film 31 is coated thereon. Moreover, via electrodes 41, 42 and 43 are formed. The thin film capacitor TFC is thus constituted. In addition, through-silicon vias electrically conducted to the via electrodes 41 and 42 are formed on the substrate 10C.

Then, the substrate 10L including the thin film inductor TFL formed thereon, illustrated in FIGS. 14(A) and 14(B), and the substrate 10C including the thin film capacitor TFC formed thereon are bonded to each other at their back surfaces with an anisotropic conductive film (AFC) interposed between both the substrates. As a result, a structure illustrated in FIGS. 15(A) and 15(B) is obtained.

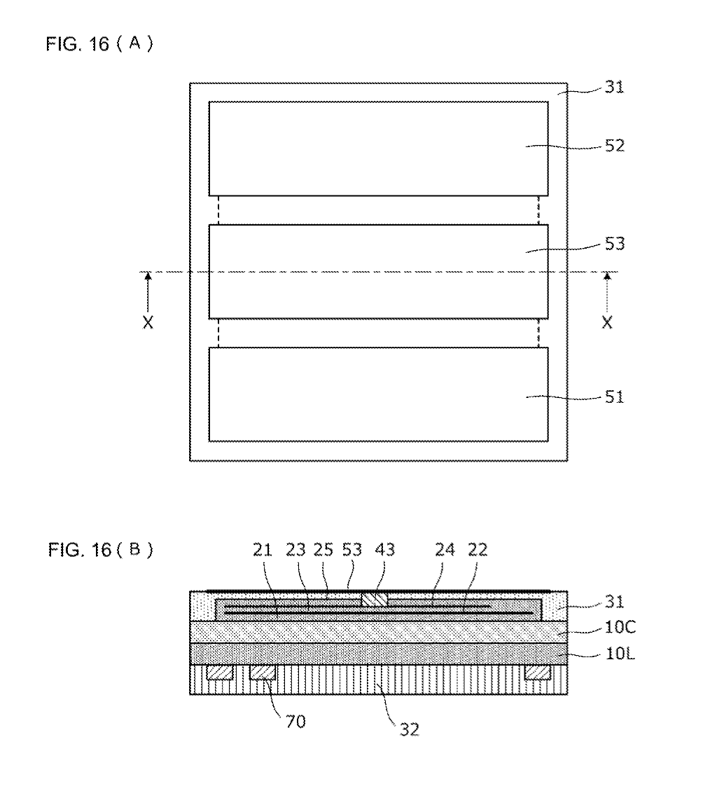

Step (4) Then, as illustrated in FIGS. 16(A) and 16(B), terminal electrodes 51, 52 and 53 are formed by forming a Cu plating film on a surface of the solder resist film 31, and by patterning the Cu plating film.

As described above in this embodiment, the thin film LC component may be constituted by forming the thin film capacitor and the thin film inductor on separate substrates, and then bonding both the substrates to each other.

### Third Embodiment

A third embodiment represents an example of a mounting structure of a thin film LC component and an example of an electronic component including the thin film LC component.

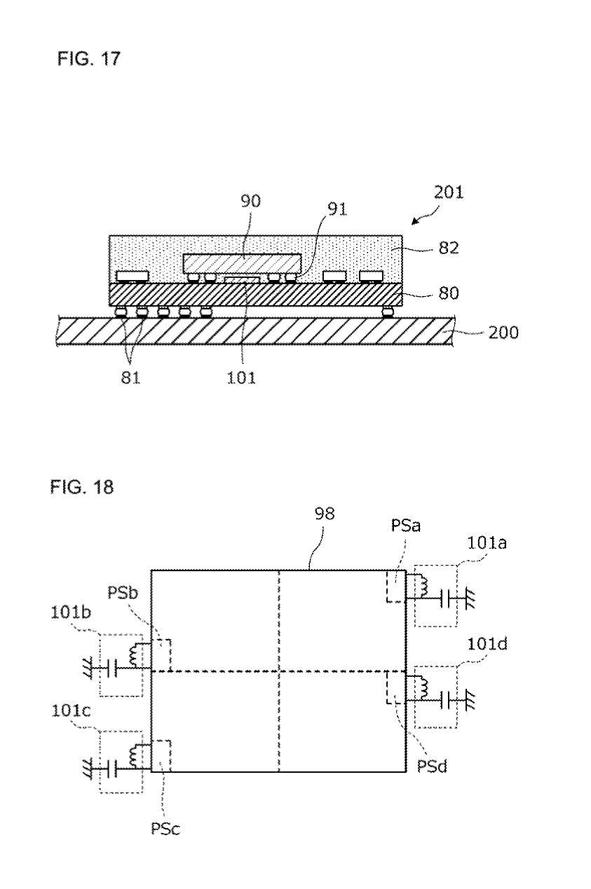

FIG. 17 is a sectional view of an electronic component of a SiP (system in a package) structure according to a third embodiment. In this electronic component, a semiconductor chip 90 and other chip components are mounted to an upper surface of a mounting substrate 80. The semiconductor chip 90 is a package of BGA (Ball Grid Array) type using solder balls 91, and is face-down mounted to the mounting substrate 80 with solder bumps interposed therebetween. The thin film LC component 101 is mounted to the mounting substrate 80 at the same position as where the semiconductor chip 90 is mounted. In other words, the thin film LC component 101 is arranged in a gap between a face plane of the semiconductor chip 90 and the mounting substrate 80. A structure of the thin film LC component 101 is as described in the first embodiment. The solder balls 91 of the semiconductor chip 90 preferably have a diameter of 250 μm before the mounting, and a diameter of about 200 μm after the mounting. Accordingly, with the thin film LC component 101 having a thickness of not more than 100 μm, the thin film LC component 101 can be arranged in the gap between the bottom face plane of the semiconductor chip 90 and the top surface of the mounting substrate 80. Taking into account contraction of the solder balls 91, the thickness of the thin film LC component 101 is preferably not more than 70 μm and more preferably not more than 50 μm.

An electronic component 201 of the Sip structure is achieved by sealing a space above the mounting substrate 80 with a sealing resin 82. The electronic component 201 is preferably also a package of BGA (Ball Grid Array) type using solder balls 81, and is surface-mounted to a circuit board 200.

It is to be noted that, without limitation, the thin film LC component 101 may be bonded to the semiconductor chip 90 instead of the mounting substrate 80.

### Fourth Embodiment

A fourth embodiment represents an example in which the thin film LC component is applied to a microprocessor including a plurality of circuits operated with different power supply voltages.

FIG. 18 is a conceptual view illustrating connection structures of smoothing circuits, which are connected to a microprocessor, according to the fourth embodiment. A microprocessor chip 98 includes a plurality of circuit blocks operated with different power supply voltages. Individual power supply circuits PSa, PSb, PSc and PSd, corresponding to the power supply voltages, are formed in the circuit blocks in a one-to-one relation. Smoothing circuits 101a, 101b, 101c and 101d of the power supply circuits PSa, PSb, PSc and PSd are disposed outside the microprocessor chip 98 and are connected thereto through wiring patterns on a substrate. The smoothing circuits 101a, 101b, 101c and 101d are the above-described thin film LC components. Those thin film LC components are arranged in a gap between the microprocessor chip and the substrate.

### Fifth Embodiment

A fifth embodiment represents an example of a thin film LC component including a plurality of thin film inductors.

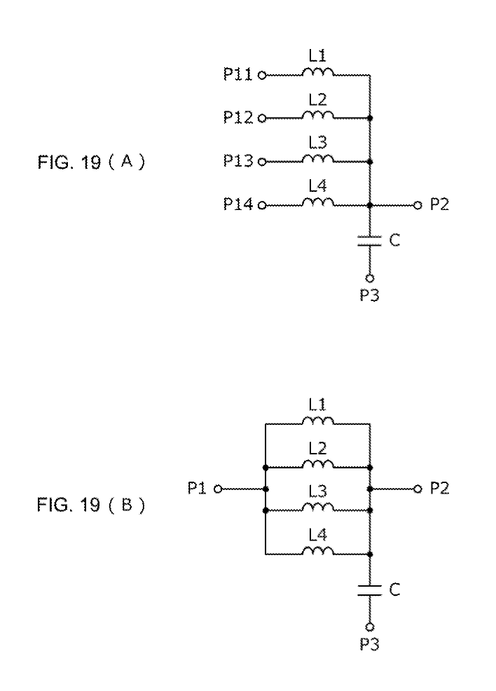

FIGS. 19(A) and 19(B) are each a circuit diagram of a thin film LC component according to the fifth embodiment. In an example illustrated in FIG. 19(A), first ends of four thin film inductors L1, L2, L3 and L4 are electrically conducted to ports P11, P12, P13 and P14, respectively, while second ends of the thin film inductors L1, L2, L3 and L4 are connected in common and electrically conducted to a port P2. Opposite ends of a thin film capacitor C are electrically conducted to the port P2 and a port P3, respectively. An example illustrated in FIG. 19(B) is different from the example illustrated in FIG. 19(A) in that the first ends of the four thin film inductors L1, L2, L3 and L4 are connected in common and electrically conducted to the port P1.

With the structure illustrated in FIG. 19(A), a time constant of the thin film LC component can be changed depending on selective connection between a circuit, such as a power supply circuit, and any one of the ports P11, P12, P13 and P14.

With the structure illustrated in FIG. 19(B), a direct-current resistance (DCR) can be reduced because the four thin film inductors L1, L2, L3 and L4 are conducted in parallel.

### Other Embodiments

While the first embodiment illustrates an example in which almost the entirety of the thin film inductor TFL is formed in the region overlapping the thin film capacitor TFC when viewing the substrate 10 in plan, part of the thin film inductor TFL may be formed in the region overlapping the thin film capacitor TFC. When at least part of the thin film inductor TFL is formed in the region overlapping the thin film capacitor TFC, the area of a region where the thin film capacitor TFC and the thin film inductor TFL are formed is reduced when viewed in plan.

While, in the example illustrated in FIGS. 1(A), 1(B) and 1(C), the conductor pattern 70 is formed directly on the surface of the substrate 10 given as the Si substrate, a protective film made of SiO2, for example, may be formed on a surface of the Si substrate, and the conductor pattern 70 may be formed on a surface of the protective film.

While the first embodiment represents the example in which a high-resistance Si substrate is used as the substrate, a glass substrate, an alumina ceramic substrate, or the like may also be used instead.

While, in the first embodiment, the thin film capacitor is first formed on the substrate and the thin film inductor is formed later thereon, the order of forming the thin film capacitor and the thin film inductor on the substrate may be reversed. Furthermore, between the step of forming the thin film capacitor and the step of forming the thin film inductor, the substrate may be polished to reduce its thickness.

In the first embodiment, the through-silicon vias (TSV's) are formed in the substrate (high-resistance Si substrate) 10. The through-silicon vias are each formed by boring a through-hole in the Si substrate, and filling Cu into the through-hole by plating. However, a through conduction path may be formed instead of the TSV by doping, namely by implanting an impurity into the Si substrate.

While the first embodiment represents the example of forming the solder resist films 31 and 32 that are organic interlayer insulating films, inorganic insulating films may be formed instead by a plasma CVD process, for example. Alternatively, the insulating film may be formed by bonding an insulating resin sheet.

While, in the above embodiments, a semiconductor substrate is used, by way of example, as the “substrate” in the present invention, a glass substrate or a ceramic substrate may also be used.

Finally, it is to be noted that the above description of the embodiments is not restrictive, but illustrative in all respects. The above embodiments can be modified and changed as appropriate by those skilled in the art. For instance, the individual structures described in the different embodiments can be partially replaced or combined with each other. The scope of the present invention is defined in not the above description of the embodiments, but in Claims. Moreover, the scope of the present invention is intended to include all modifications that are equivalent to Claims in terms of meaning and scope.

### REFERENCE SIGNS LIST

H1, H2, H3 . . . hole

H61, H62 . . . hole

L1, L2, L3, L4 . . . thin film inductor

P1, P2, P3 . . . port

P11, P12, P13, P14 . . . port

PSa, PSb, PSc, PSd . . . power supply circuit

S1 . . . first surface

S2 . . . second surface

TFC . . . thin film capacitor

TFL . . . thin film inductor

TSV . . . through-silicon via

10, 10C, 10L . . . substrate

21, 23, 25 . . . BST film

22, 24 . . . Pt electrode film

31, 32 . . . solder resist film (insulating layer)

41, 42, 43 . . . via electrode

51, 52, 53 . . . terminal electrode

61, 62 . . . through-silicon via

70 . . . conductor pattern

80 . . . mounting substrate

81, 91 . . . solder ball

82 . . . sealing resin

90 . . . semiconductor chip

98 . . . microprocessor chip

101, 102 . . . thin film LC component

101a, 101b, 101c, 101d . . . smoothing circuit

200 . . . circuit board

201 . . . electronic component

221, 222 . . . Pt electrode film

1. A thin film LC component, comprising:
a substrate that has first and second opposing surfaces;
a thin film capacitor located on the first surface;
a thin film inductor located on a region of the second surface, the region at least partially overlapping the thin film capacitor when viewed in plan;
interlayer connection conductors located in the substrate and connecting the thin film capacitor to the thin film inductor;
an insulating layer located over the first surface and covering the thin film capacitor; and
a plurality of terminal electrodes located on a surface of the insulating layer and being connected to both the thin film capacitor and the thin film inductor, the terminal electrodes being connected to a circuit on a mounting substrate.

2. The thin film LC component according to claim 1, wherein:
each of the thin film inductor and the thin film capacitor have respective first and second ends;
the first end of the thin film capacitor and the second end of the thin film inductor are connected to each other; and
the plurality of terminal electrodes include at least three terminal electrodes that are connected to the first end of the thin film capacitor, a second end of the thin film capacitor, and a first end of the thin film inductor, respectively.

3. The thin film LC component according to claim 2, wherein:
the thin film inductor includes a plurality of thin film inductors each having a respective first end and a second end, and
the plurality of terminal electrodes include a terminal electrode that is connected to each of the first ends of the plurality of thin film inductors.

4. The thin film LC component according to claim 1 wherein:
the thin film capacitor includes a first electrode film extending parallel to the first surface;
a second electrode film opposing to the first electrode film; and
a dielectric thin film interposed between the first electrode film and the second electrode film, the dielectric thin film being a barium strontium titanate thin film.

5. The thin film LC component according to claim 2 wherein:
the thin film capacitor includes a first electrode film extending parallel to the first surface;
a second electrode film opposing to the first electrode film; and
a dielectric thin film interposed between the first electrode film and the second electrode film, the dielectric thin film being a barium strontium titanate thin film.

6. The thin film LC component according to claim 3 wherein:
the thin film capacitor includes a first electrode film extending parallel to the first surface;
a second electrode film opposing to the first electrode film; and
a dielectric thin film interposed between the first electrode film and the second electrode film, the dielectric thin film being a barium strontium titanate thin film.

7. The thin film LC component according to claim 1, wherein a total thickness of the substrate, the thin film capacitor, the thin film inductor, and the insulating layer is not more than 100 μm.

8. The thin film LC component according to claim 2, wherein a total thickness of the substrate, the thin film capacitor, the thin film inductor, and the insulating layer is not more than 100 μm.

9. The thin film LC component according to claim 3, wherein a total thickness of the substrate, the thin film capacitor, the thin film inductor, and the insulating layer is not more than 100 μm.

10. The thin film LC component according to claim 4, wherein a total thickness of the substrate, the thin film capacitor, the thin film inductor, and the insulating layer is not more than 100μm.

11. The thin film LC component of claim 1, wherein the thin film capacitor and the thin film inductor are formed by a thin film process.

12. A combination comprising:
a semiconductor chip, a capacitor, and an inductor mounted on a mounting substrate;
the semiconductor chip being face-down mounted to the mounting substrate with bumps interposed therebetween, and
the capacitor and the inductor are each a thin film LC component comprising:
a substrate having first and second opposing surfaces;
a thin film capacitor located on the first surface;
a thin film inductor located on a region of the second surface, the region at least partially overlapping the thin film capacitor when viewed in plan;
interlayer connection conductors extending through the substrate and connecting the thin film capacitor to the thin film inductor;
an insulating layer located over the first surface and covering the thin film capacitor; and
terminal electrodes located on a surface of the insulating layer and being connected to the thin film capacitor and the thin film inductor; and
the thin film LC component being disposed in a gap between the mounting substrate and the semiconductor chip, and being mounted to the mounting substrate with the terminal electrodes connected to a circuit on the mounting substrate.

13. The combination of claim 12, wherein the thin film capacitor and the thin film inductor are formed by a thin film process.
